(19) United States
(12) Patent Application Publication
(10) Pub. No.: US 2025/0140737 A1
(43) Pub. Date: May 1, 2025

(54) SEMICONDUCTOR MANUFACTURING APPARATUS AND SEMICONDUCTOR DEVICE

(71) Applicant: Mitsubishi Electric Corporation, Tokyo (JP)

(72) Inventor: Koichi TOKUBO, Fukuoka (JP)

(73) Assignee: Mitsubishi Electric Corporation, Tokyo (JP)

(21) Appl. No.: 18/776,116

(22) Filed: Jul. 17, 2024

(30) Foreign Application Priority Data
Oct. 26, 2023 (JP) 2023-183712

(51) Int. Cl. H01L 23/00

(52) U.S. Cl. CPC H01L 24/78; H01L 24/45; H01L 24/48; H01L 2224/45014; H01L 2224/48137; H01L 2224/48175; H01L 2224/7855

(57) ABSTRACT

A semiconductor manufacturing apparatus includes: a wire guide to supply a wire; a tool to bond the wire supplied by the wire guide to a plurality of bonded portions of each of the semiconductor devices; a first blade to half cut a remaining portion of the wire other than a portion between the plurality of bonded portions; and a second blade having a cutting edge whose angle is an acute angle smaller than an angle of a cutting edge of the first blade and to cut the half cut portion of the wire.

### BACKGROUND OF THE INVENTION

### Field of the Invention

The present disclosure relates to semiconductor manufacturing apparatuses and semiconductor devices.

### Description of the Background Art

An aluminum wire has conventionally been used to connect bonded members, such as semiconductor elements, in the manufacture of a semiconductor device. After bonding of the aluminum wire, an unnecessary remaining portion of the aluminum wire is cut.

For example, Japanese Patent Application Laid-Open No. 2002-26058 discloses a method of cutting an aluminum wire by half cutting a remaining portion of the aluminum wire at an aerial position near a semiconductor element and performing tearing operation on the half cut portion not to scratch the semiconductor element during cutting of the aluminum wire.

A semiconductor device has recently become more space-saving and sophisticated. As a result, for a high-temperature operating long-lived semiconductor device, it is contemplated to replace conventional wiring technology using an aluminum wire with wiring technology using a copper wire having a higher hardness than the aluminum wire or any other metal wire expected to increase durability of the semiconductor device.

The wiring technology using the copper wire, however, has a problem in that a higher load is put on a cutting member, such as a cutter, as the copper wire has a higher hardness than the aluminum wire, resulting in progression of wear and an increase in frequency of breakage of the cutting member.

### SUMMARY

It is an object of the present disclosure to provide technology enabling reduction in load put on a cutting member when a semiconductor device including, as wiring, wires having a higher hardness than aluminum wires is manufactured.

A semiconductor manufacturing apparatus according to the present disclosure is a semiconductor manufacturing apparatus to manufacture a semiconductor device. The semiconductor manufacturing apparatus includes a wire supply, a tool, a first blade, and a second blade. The wire supply supplies a wire. The tool bonds the wire supplied by the wire supply to a plurality of bonded portions of the semiconductor device. The first blade half cuts a remaining portion of the wire other than a portion between the plurality of bonded portions. The second blade has a cutting edge whose angle is an acute angle smaller than an angle of a cutting edge of the first blade and cuts the half cut portion of the wire.

The remaining portion of the wire is cut half at a time with the first blade 5 and the second blade 6, so that, when the semiconductor device including, as wiring, wires having a higher hardness than aluminum wires is manufactured, a load put on the first blade and the second blade as cutting members can be reduced compared with a case where the wire is cut all at once.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a side view illustrating configurations of a wire guide and its surroundings of a semiconductor manufacturing apparatus according to an embodiment;

FIG. 2 is a perspective view of a case type semiconductor device;

FIG. 3 is a cross-sectional view of the case type semiconductor device;

FIG. 4 is a side view of a lead frame type semiconductor device;

FIG. 5 is a cross-sectional view of the lead frame type semiconductor device;

FIG. 6 is a side view illustrating examples of drive mechanisms to drive a first blade and a second blade of the semiconductor manufacturing apparatus according to the embodiment;

FIG. 7 is a side view illustrating other examples of the drive mechanisms to drive the first blade and the second blade of the semiconductor manufacturing apparatus according to the embodiment;

FIG. 8 is a side view illustrating examples of cut surfaces of a wire;

FIG. 9 is a side view illustrating other examples of the cut surfaces of the wire;

FIG. 10 is a side view illustrating operation in a wiring process of the semiconductor manufacturing apparatus according to the embodiment;

FIG. 11 is a side view illustrating operation in the wiring process of the semiconductor manufacturing apparatus according to the embodiment;

FIG. 12 is a side view illustrating operation in the wiring process of the semiconductor manufacturing apparatus according to the embodiment;

FIG. 13 is a side view illustrating operation in the wiring process of the semiconductor manufacturing apparatus according to the embodiment;

FIG. 14 is a side view illustrating operation in the wiring process of the semiconductor manufacturing apparatus according to the embodiment;

FIG. 15 is a side view illustrating operation in the wiring process of the semiconductor manufacturing apparatus according to the embodiment;

FIG. 16 is a side view illustrating operation in the wiring process of the semiconductor manufacturing apparatus according to the embodiment;

FIG. 17 is a side view illustrating operation in the wiring process of the semiconductor manufacturing apparatus according to the embodiment; and

FIG. 18 is a side view illustrating operation in the wiring process of the semiconductor manufacturing apparatus according to the embodiment.

### DESCRIPTION OF THE PREFERRED EMBODIMENTS

### Embodiment

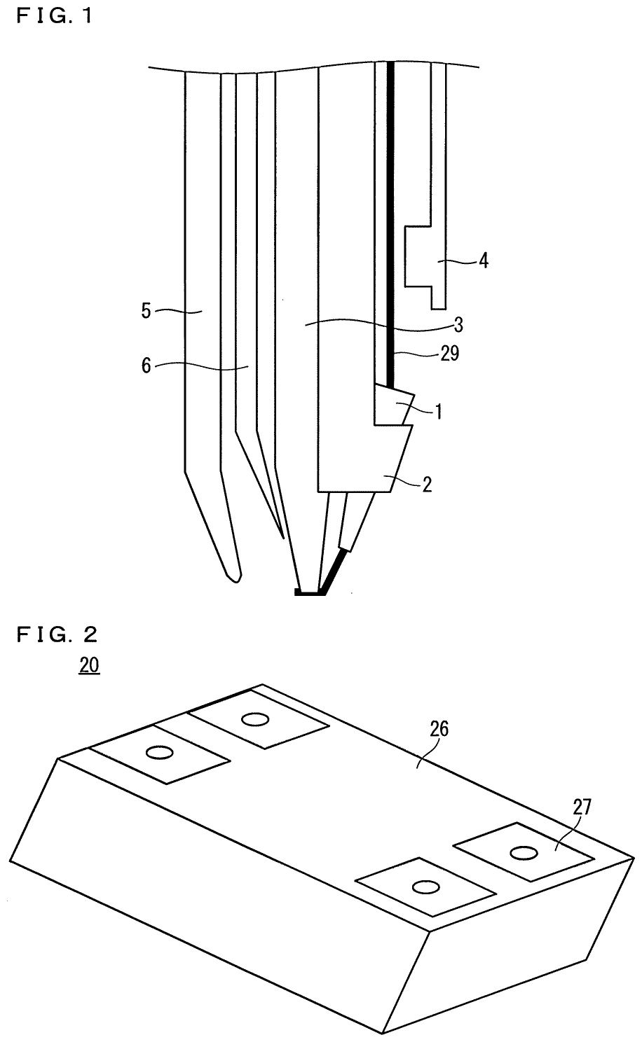

An embodiment will be described below with reference to the drawings. FIG. 1 is a side view illustrating configurations of a wire guide 1 and its surroundings of a semiconductor manufacturing apparatus 100 according to the embodiment.

As illustrated in FIG. 1, the semiconductor manufacturing apparatus 100 is an apparatus to manufacture a semiconductor device and is specifically an apparatus to perform a wiring process as part of the manufacture of the semiconductor device.

### (Configuration of Semiconductor Device)

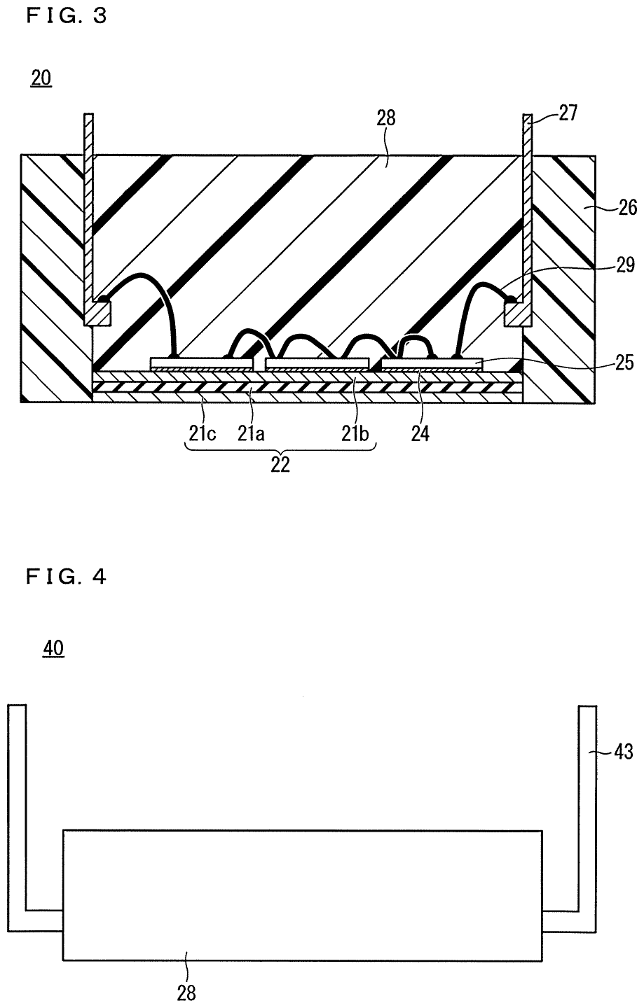

A case type semiconductor device 20 manufactured by the semiconductor manufacturing apparatus 100 will briefly be described first. FIG. 2 is a perspective view of the case type semiconductor device 20. FIG. 3 is a cross-sectional view of the case type semiconductor device 20. As illustrated in FIGS. 2 and 3, the case type semiconductor device 20 includes an insulating substrate 22, semiconductor elements 25, a case 26, terminals 27, a sealing resin 28, and wires 29. The insulating substrate 22 includes an insulating layer 21a, a metal pattern 21b disposed on an upper surface of the insulating layer 21a, and a metal pattern 21c disposed on a lower surface of the insulating layer 21a. The metal patterns 21b and 21c are formed of copper, aluminum, or nickel. When the metal patterns 21b and 21c are copper patterns, the copper patterns may be subjected to nickel plating and the like.

The semiconductor elements 25 are mounted to the metal pattern 21b via bonding materials 24. Examples of the semiconductor elements 25 include insulated gate bipolar transistors (IGBTs), reverse conducting-IGBTs (RC-IGBTs), metal oxide semiconductor field effect transistors (MOSFETs), and free wheeling diodes (FWDs). A material for the semiconductor elements 25 may be silicon (Si) as usual and may be a wide bandgap semiconductor, such as silicon carbide (SiC), gallium nitride (GaN), and diamond. The wide bandgap semiconductor as the material for the semiconductor elements 25 allows for stable operation at a high temperature and a high voltage and an increase in switching speed. The number of semiconductor elements 25 may be one and may be two or more.

The case 26 is in the shape of a rectangular frame and is fixed to side surfaces of the insulating substrate 22 to laterally surround the insulating substrate 22 and the semiconductor elements 25. The terminals 27 are attached to inner peripheral surfaces of the case 26. A method of attaching the terminals 27 is not limited to this method, and the terminals 27 may be embedded in the sealing resin 28 and may integrated with the case 26 by insert molding. One end side of each of the terminals 27 protrudes outward of the case 26 and is bent horizontally (see FIG. 2). As illustrated in FIG. 3, the terminals 27 may extend vertically without being bent horizontally.

The wires 29 connect the semiconductor elements 25 and the terminals 27 and connect the semiconductor elements 25. Each of the wires 29 is formed of metal having a higher hardness than aluminum and has a circular cross section with a diameter of 100 μm or more and 600 μm or less and is a copper wire, for example. Each of the wires 29 may be a ribbon wire of copper having a rectangular cross section with a width of approximately 0.1 mm or more and 20 mm or less and a height of approximately 0.1 mm or more and 5 mm or less, for example.

The case 26 is filled with the sealing resin 28, and the sealing resin 28 seals the semiconductor elements 25 mounted to the insulating substrate 22. An example of the sealing resin 28 includes an epoxy resin.

After the semiconductor elements 25 are mounted to the insulating substrate 22, a wiring process of performing internal wiring using the wires 29 is performed. The wiring process is a process of connecting a first bonded portion and a second bonded portion, such as the semiconductor elements 25 and the terminals 27, the semiconductor elements 25 and the metal pattern 21b formed in the upper surface of the insulating substrate 22, and the semiconductor elements 25 (one semiconductor element 25 and another semiconductor element 25), of the semiconductor device 20 using the wires 29 and is an important process for the semiconductor device 20 to perform an electrical function.

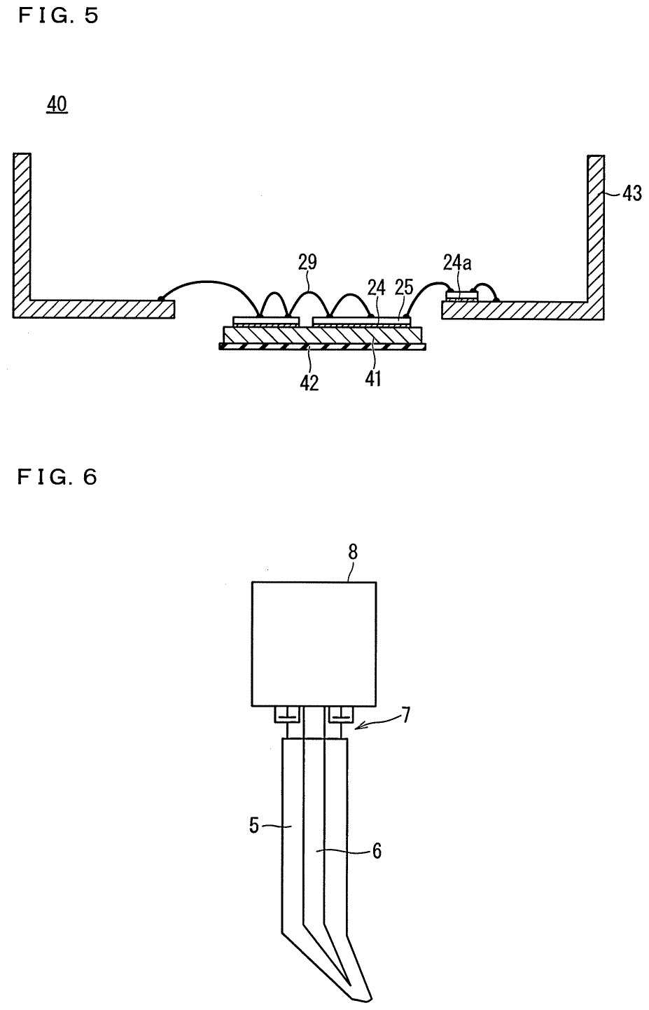

The semiconductor manufacturing apparatus 100 can be used to manufacture not only the case type semiconductor device 20 but also a lead frame type semiconductor device 40. The lead frame type semiconductor device 40 will briefly be described. FIG. 4 is a side view of the lead frame type semiconductor device 40. FIG. 5 is a cross-sectional view of the lead frame type semiconductor device 40.

As illustrated in FIGS. 4 and 5, the lead frame type semiconductor device 40 includes a lead frame 41, an insulating sheet 42, the semiconductor elements 25, the wires 29, lead frames 43, and the sealing resin 28.

The insulating sheet 42 is adhered to a lower surface of the lead frame 41. One or more of the semiconductor elements 25 are mounted to an upper surface of the lead frame 41 via the bonding materials 24, and remaining one or more of the semiconductor elements 25 are mounted to upper surfaces of the lead frames 43 via bonding materials 24a having different properties from the bonding materials 24. Examples of the bonding materials 24 and 24a include solder, silver pastes, and sintered pastes. The wires 29 connect the semiconductor elements 25 and the lead frames 43 and connect the semiconductor elements 25. One or more of the wires 29 connected to the one or more of the semiconductor elements 25 mounted to the upper surfaces of the lead frames 43 each sometimes have a different wire diameter from the other one or more of the wires 29. The sealing resin 28 is in the shape of a cuboid and seals the lead frame 41, the insulating sheet 42, the semiconductor elements 25, the wires 29, and the lead frames 43. The sealing resin 28 is not illustrated in FIG. 5.

### (Configuration of Semiconductor Manufacturing Apparatus)

The semiconductor manufacturing apparatus 100 will be described next. As illustrated in FIG. 1, the semiconductor manufacturing apparatus 100 includes the wire guide 1 as a wire supply, a wire guide holder 2, a tool 3, a wire clamper 4, a first blade 5, and a second blade 6. A mechanism including the wire guide 1, the wire guide holder 2, the tool 3, the wire clamper 4, the first blade 5, and the second blade 6 is hereinafter also referred to as a wire bond mechanism. That is to say, the semiconductor manufacturing apparatus 100 includes the wire bond mechanism. The semiconductor manufacturing apparatus 100 further includes a reel around which a wire 29 is wound although the reel is not illustrated. The reel supplies the wire 29 to the wire guide 1.

The wire guide 1 is in the shape of a cone and is held by the wire guide holder 2. The wire guide 1 has therein a through hole (not illustrated) extending along a longitudinal direction thereof. The wire 29 supplied by the reel is inserted into the through hole of the wire guide 1, and the wire guide 1 guides the wire 29 from an inlet to an outlet of the through hole. The inlet of the through hole is located at an upper end of the wire guide 1, and the outlet of the through hole is located at a lower end of the wire guide 1.

The wire clamper 4 is disposed above the wire guide 1 and locks, at a position above the wire guide 1, the wire 29 supplied by the reel to the wire guide 1.

The tool 3 is disposed below the wire guide 1 so that a leading end of the tool 3 is located around the outlet of the through hole of the wire guide 1. The tool 3 applies vibrations while pressing the wire 29 supplied from the wire guide 1 to generate frictional heat and melt the wire 29 due to frictional heat and bonds the wire 29 to the first bonded portion and the second bonded portion of the semiconductor device 20. It goes without saying that, when a method referred to as stitch bonding is used, the wire 29 is connected to three or more bonded portions including not only the first bonded portion and the second bonded portion but also a third bonded portion, a fourth bonded portion, and the like.

The semiconductor manufacturing apparatus 100 is a front cut type semiconductor manufacturing apparatus. The first blade 5 is thus disposed on a front side of the tool 3, that is, on an opposite side of the tool 3 from the wire guide holder 2. The first blade 5 is also disposed so that a cutting edge as a leading end of the first blade 5 is located around the leading end of the tool 3. The cutting edge of the first blade 5 is spherical, rectangular, or trapezoidal, and an angle of the cutting edge of the first blade 5 is an obtuse angle. The first blade 5 half cuts a remaining portion of the wire 29 other than a portion between the first bonded portion and the second bonded portion. Half cutting herein refers to cutting the wire 29 to a thickness approximately half a diameter of the wire 29.

The first blade 5 is formed to have a width greater than the diameter of the wire 29, and a portion, such as the cutting edge, of the first blade 5 to be in contact with the wire 29 has been polish finished. This avoids progression of breakage of the first blade 5 during cutting operation due to a fine flaw in the first blade 5 and the like and allows for smooth cutting operation.

The second blade 6 is disposed between the tool 3 and the first blade 5. The second blade 6 is also disposed so that a cutting edge as a leading end of the second blade 6 is located around the leading end of the tool 3. An angle of the cutting edge of the second blade 6 is an acute angle smaller than the angle of the cutting edge of the first blade 5, and the cutting edge of the second blade 6 is located above the cutting edge of the first blade 5 when the wire bond mechanism is at a rest. The second blade 6 cuts the portion of the wire 29 half cut by the first blade 5. A positional relationship between the cutting edge of the first blade 5 and the cutting edge of the second blade 6 varies depending on configurations of drive mechanisms to drive the first blade 5 and the second blade 6 and is thus not limited to the above-mentioned positional relationship.

The second blade 6 is formed to have a width greater than the diameter of the wire 29, and a portion, such as the cutting edge, of the second blade 6 to be in contact with the wire 29 has been polish finished. This avoids progression of breakage of the second blade 6 during cutting operation due to a fine flaw in the second blade 6 and the like and allows for smooth cutting operation.

The first blade 5 and the second blade 6 are arranged on an opposite side of the tool 3 from the wire guide 1, and the second blade 6 is disposed closer to the tool 3 than the first blade 5 is, but arrangement is not limited to this arrangement, and the first blade 5 may be disposed closer to the tool 3 than the second blade 6 is.

The semiconductor manufacturing apparatus 100 is not limited to that of the front cut type and may be of a rear cut type. In this case, the first blade 5 and the second blade 6 are only required to be arranged between the tool 3 and the wire guide 1.

The semiconductor manufacturing apparatus 100 may have a configuration in which the front cut type and the rear cut type are combined. In this case, the first blade 5 is only required to be disposed between the tool 3 and the wire guide 1, and the second blade 6 is only required to be disposed on an opposite side of the tool 3 from the wire guide 1.

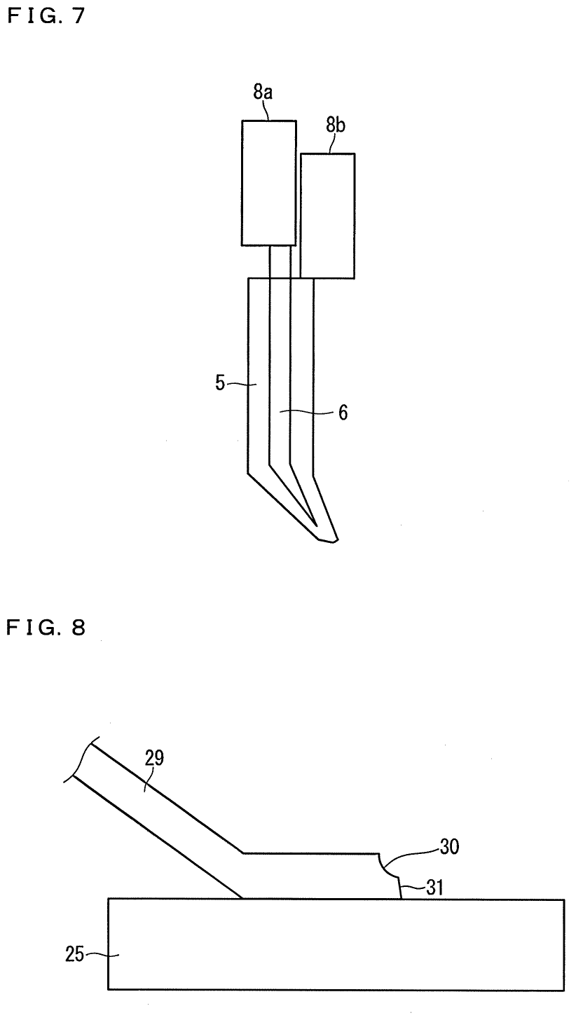

The drive mechanisms to drive the first blade 5 and the second blade 6 will be described next. FIG. 6 is a side view illustrating examples of the drive mechanisms to drive the first blade 5 and the second blade 6 of the semiconductor manufacturing apparatus 100 according to the embodiment. FIG. 7 is a side view illustrating other examples of the drive mechanisms to drive the first blade 5 and the second blade 6 of the semiconductor manufacturing apparatus 100 according to the embodiment.

As illustrated in FIG. 6, the first blade 5 is moved upward and downward by a damper mechanism 7. The second blade 6 is moved upward and downward by a motor 8. The damper mechanism 7 can be configured less expensively than the motor 8 but has a lower accuracy of positioning of the first blade 5 than the motor 8, so that an accuracy of machining of a cut surface 30 is low. It is thus desirable to use the motor 8 for driving of the second blade 6 required to have a higher machining accuracy. The first blade 5 is not required to have a higher machining accuracy than the second blade 6, so that the damper mechanism 7 is used for driving of the first blade 5. When costs of components of the semiconductor manufacturing apparatus 100 are not an issue, a motor 8a may be used for driving of the first blade 5, and a motor 8b may be used for driving of the second blade 6 as illustrated in FIG. 7.

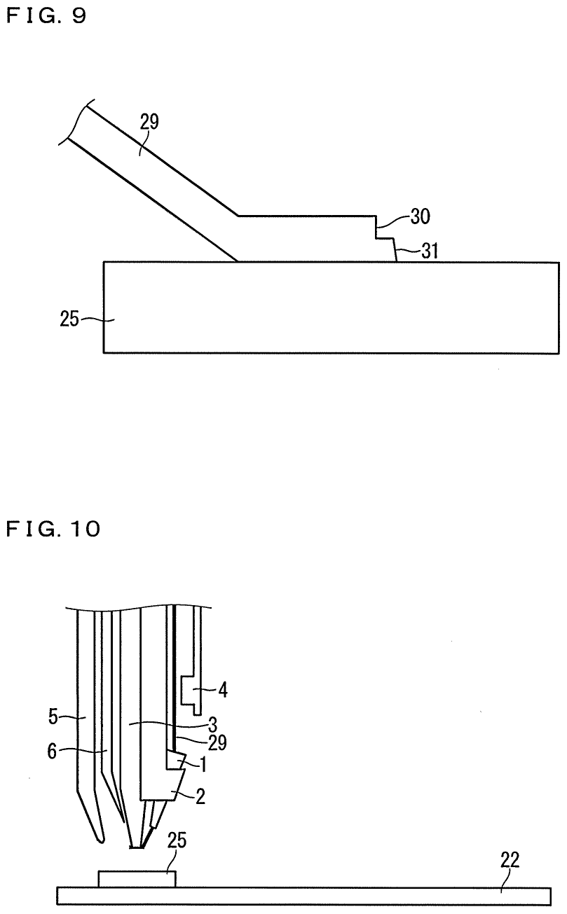

Cut surfaces of the wire 29 will be described next. FIG. 8 is a side view illustrating examples of the cut surfaces of the wire 29. FIG. 9 is a side view illustrating other examples of the cut surfaces of the wire 29.

After being half cut with the first blade 5, the wire 29 is cut with the second blade 6, so that two different continuous cut surfaces 30 and 31 are formed as illustrated in each of FIGS. 8 and 9. Specifically, the cut surface 30 with the first blade 5 and the cut surface 31 with the second blade 6 are formed to be vertically continuous. FIG. 8 illustrates the cut surface 30 when the cutting edge of the first blade 5 is spherical, and FIG. 9 illustrates the cut surface 30 when the cutting edge of the first blade 5 is rectangular.

### (Operation of Semiconductor Manufacturing Apparatus)

Operation of the semiconductor manufacturing apparatus 100 will be described next. FIGS. 10 to 18 are side views illustrating operation in the wiring process of the semiconductor manufacturing apparatus 100 according to the embodiment. While a case where the semiconductor device 20 is manufactured will be described below, the semiconductor device 40 is manufactured in a similar manner to the semiconductor device 20, so that description on a case where the semiconductor device 40 is manufactured will be omitted.

First, as illustrated in FIG. 10, the wire bond mechanism including the wire guide 1, the wire guide holder 2, the tool 3, the wire clamper 4, the first blade 5, and the second blade 6 is lowered toward one of the semiconductor elements 25 as the first bonded portion. The wire bond mechanism is generally lowered to a distance of approximately 500 μm or more and 1000 μm or less from the first bonded portion at a high speed and then lowered at a low speed referred to as a search speed to detect the first bonded portion. The wire bond mechanism is lowered at a low speed because it is necessary to consider a variation in height position of the first bonded portion.

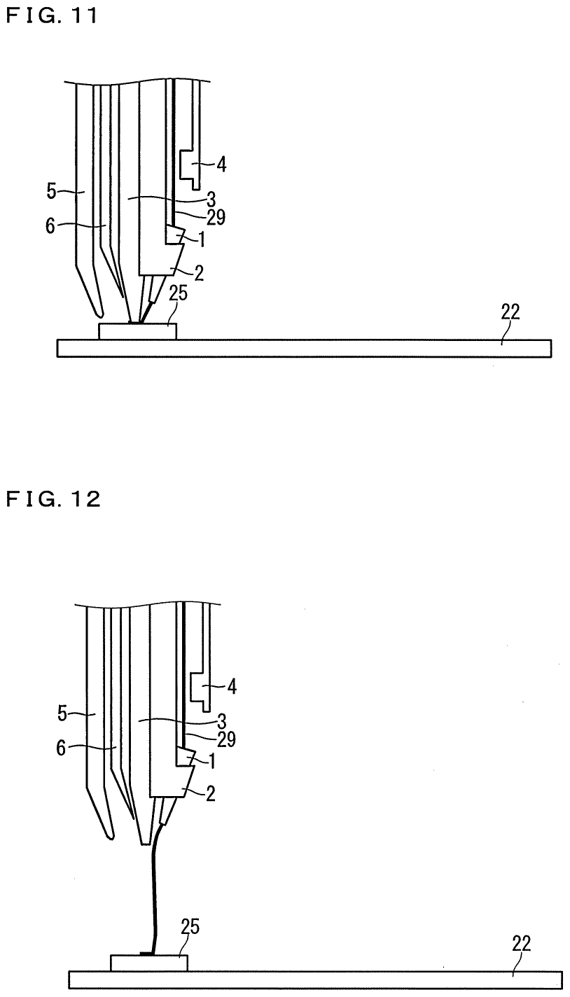

Next, as illustrated in FIG. 11, when the semiconductor manufacturing apparatus 100 detects the first bonded portion, the tool 3 outputs a load and ultrasonic vibrations required for the wiring process for a predetermined period of time. This operation completes bonding of the first bonded portion and the wire 29. A bonding time of approximately 50 ms or more and 300 ms or less is required when the wire 29 is an aluminum wire having a wire diameter of 100 μm or more and 500 μm or less, but, when the wire 29 is a copper wire, the bonding time is slightly longer than that when the wire 29 is the aluminum wire although varying depending on a wire diameter of the copper wire.

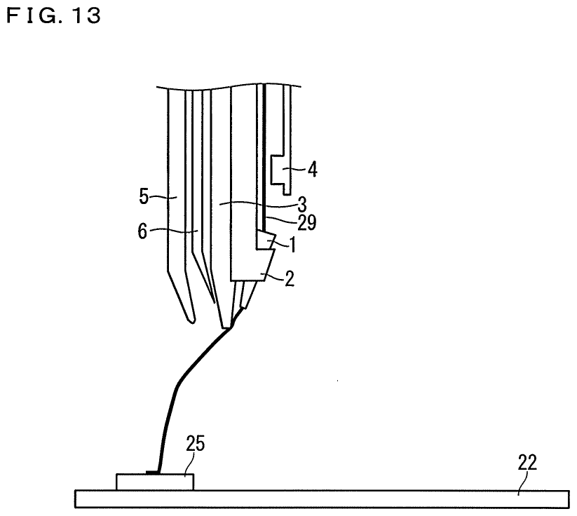

Next, upon completion of bonding of the first bonded portion and the wire 29, operation transitions to operation to shape a wiring trajectory (loop). As illustrated in FIGS. 12 and 13, the wire bond mechanism is raised and moved horizontally toward the second bonded portion. In this case, the wire bond mechanism is sometimes subjected to up and down movement, and the wire 29 is sometimes subjected to mechanical contact deformation using an unillustrated loop shaping component to shape a mountain-shaped loop and a trapezoidal loop.

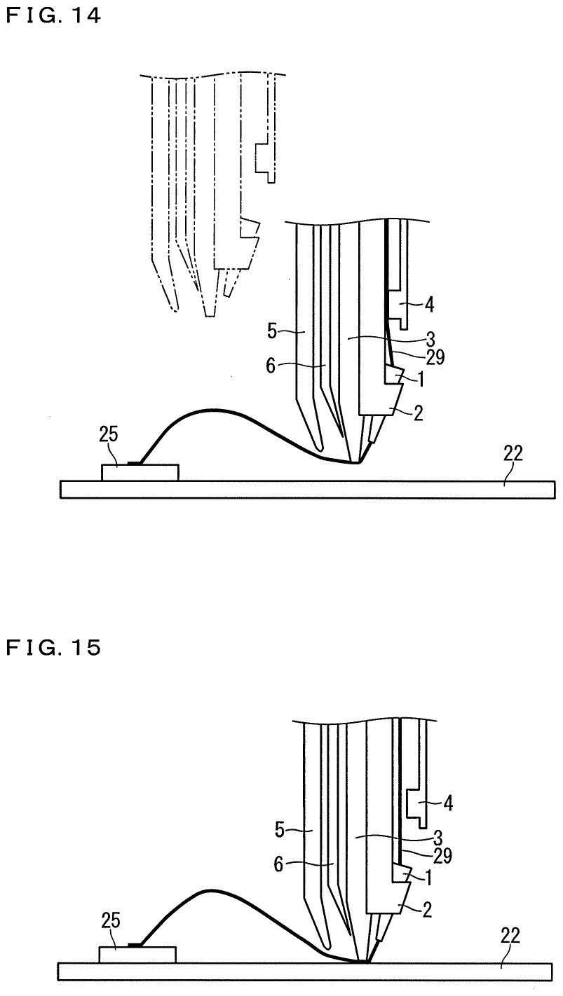

Next, as illustrated in FIG. 14, the wire bond mechanism is lowered toward the second bonded portion while performing the loop shaping operation. The wire bond mechanism before lowering is indicated in alternate long and two short dashes lines. As in operation having been described with reference to FIG. 10, the wire bond mechanism is lowered to a distance of approximately 500 μm or more and 1000 μm or less from the second bonded portion at a high speed and then lowered at a low speed referred to as the search speed to detect the second bonded portion.

Next, as illustrated in FIG. 15, when the semiconductor manufacturing apparatus 100 detects the second bonded portion, the tool 3 outputs a load and ultrasonic vibrations required for the wiring process for a predetermined period of time as in operation having been described with reference to FIG. 11. This operation completes bonding of the second bonded portion and the wire 29.

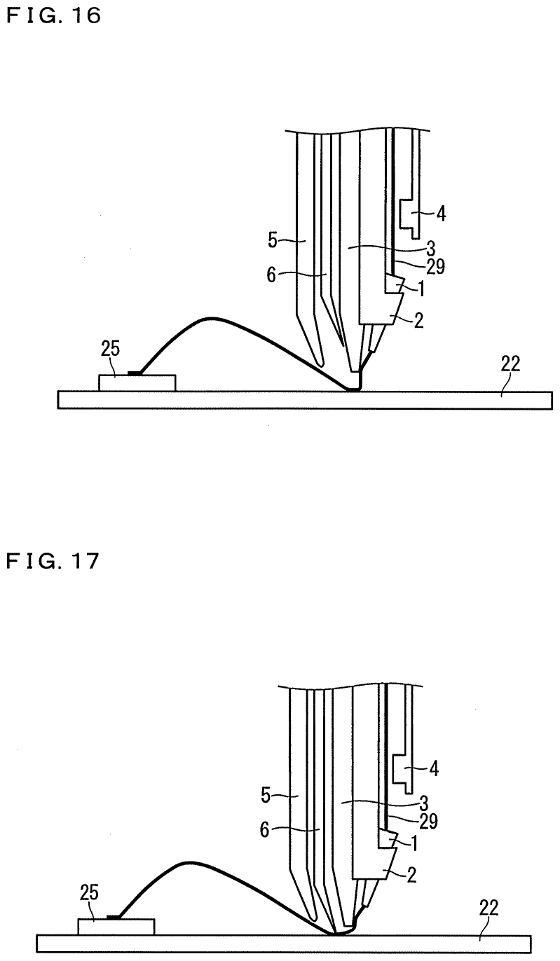

Next, as illustrated in FIG. 16, upon completion of bonding of the second bonded portion and the wire 29, the wire bond mechanism is once raised before cutting operation and performs operation to withdraw the wire 29 by a distance required for next bonding to a first point (bonding to the first bonded portion) of the wire 29. This operation is performed by a raise and horizontal movement along a wiring direction of the wire bond mechanism. When the wire 29 is ensured by the distance required for next bonding to the first point of the wire 29, operation transitions to cutting operation.

Next, as illustrated in FIG. 17, after the wire bond mechanism is lowered to a height position required for cutting of the wire 29, the first blade 5 is lowered to half cut the wire 29, and then the second blade 6 is lowered to cut the wire 29.

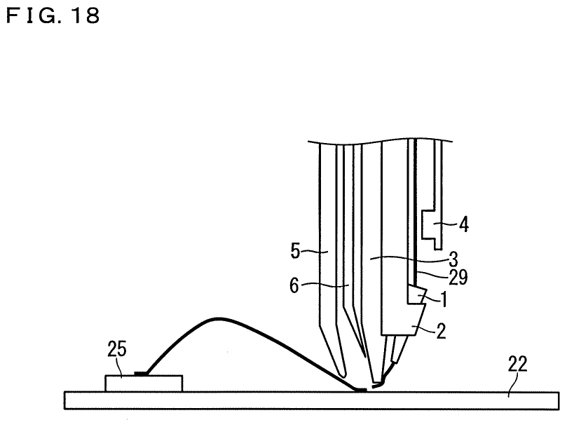

Next, as illustrated in FIG. 18, after the first blade 5 and the second blade 6 are raised, the wire bond mechanism is moved by a designated distance in the wiring direction, and, when cutting is imperfect, tearing operation is performed.

### (Effects)

As described above, the semiconductor manufacturing apparatus 100 according to the embodiment includes: the wire guide 1 to supply the wire 29; the tool 3 to bond the wire 29 supplied by the wire guide 1 to a plurality of bonded portions of each of the semiconductor devices 20 and 40; the first blade 5 to half cut the remaining portion of the wire 29 other than a portion between the plurality of bonded portions; and the second blade 6 having a cutting edge whose angle is an acute angle smaller than an angle of a cutting edge of the first blade 5 and to cut the half cut portion of the wire 29.

The remaining portion of the wire 29 is cut half at a time with the first blade 5 and the second blade 6, so that, when the semiconductor devices 20 and 40 each including, as wiring, the wires 29 having a higher hardness than aluminum wires are manufactured, a load put on the first blade 5 and the second blade 6 as cutting members can be reduced compared with a case where the wire 29 is cut all at once. As a result, wear of the first blade 5 and the second blade 6 is suppressed, and the first blade 5 and the second blade 6 are less likely to be broken, so that a semiconductor manufacturing apparatus including cutting members having longer lives than conventional cutting members can be provided.

A frequency of replacement of the first blade 5 and the second blade 6 is reduced, so that downtime of the semiconductor manufacturing apparatus 100 associated with replacement of the first blade 5 and the second blade 6 can be reduced. This can improve productivity of each of the semiconductor devices 20 and 40.

The semiconductor manufacturing apparatus 100 further includes: the damper mechanism 7 to move the first blade 5; and the motor 8 to move the second blade 6. The first blade 5 is not required to have a higher machining accuracy than the second blade 6, so that the damper mechanism 7 is used for driving of the first blade 5 to achieve reduction in cost of the semiconductor manufacturing apparatus 100.

The angle of the cutting edge of the second blade 6 is the acute angle, and thus the second blade 6 tends to wear earlier, but the angle of the cutting edge of the first blade 5 is the obtuse angle, so that wear of the second blade 6 can be suppressed by, after half cutting the wire 29 with the first blade 5, cutting the wire 29 with the second blade 6.

Each of the semiconductor devices 20 and 40 includes: the semiconductor elements 25; and the wires 29 connected to the semiconductor elements 25 and each having two different continuous cut surfaces 30 and 31. Each of the wires 29 has the cut surface 30 formed with the first blade 5 and the cut surface 31 formed with the second blade 6, so that the different continuous cut surfaces 30 and 31 clearly show that cutting has been performed twice. Furthermore, the wire 29 can have an improved effect of anchoring the sealing resin 28, so that lives of a portion where the wire 29 and the first bonded portion are bonded and a portion where the wire 29 and the second bonded portion are bonded can be improved.

The embodiment can be modified as appropriate.

Various aspects of the present disclosure will collectively be described below as appendices.

### APPENDIX 1

A semiconductor manufacturing apparatus to manufacture a semiconductor device, the semiconductor manufacturing apparatus comprising:
a wire supply to supply a wire;
a tool to bond the wire supplied by the wire supply to a plurality of bonded portions of the semiconductor device;
a first blade to half cut a remaining portion of the wire other than a portion between the plurality of bonded portions; and
a second blade to cut the half cut portion of the wire, the second blade having a cutting edge whose angle is an acute angle smaller than an angle of a cutting edge of the first blade.

### APPENDIX 2

The semiconductor manufacturing apparatus according to Appendix 1, further comprising:
a damper mechanism to move the first blade; and
a motor to move the second blade.

### APPENDIX 3

The semiconductor manufacturing apparatus according to Appendix 1 or 2, wherein
the angle of the cutting edge of the first blade is an obtuse angle.

### APPENDIX 4

A semiconductor device comprising:
a semiconductor element; and
a wire connected to the semiconductor element and having two different continuous cut surfaces.

### APPENDIX 5

The semiconductor device according to Appendix 4, wherein
the wire is a wire having a diameter of 100 μm or more and 600 μm or less and formed of metal having a higher hardness than aluminum.

### APPENDIX 6

The semiconductor device according to Appendix 4 or 5, wherein
the wire is a ribbon wire.

While the invention has been shown and described in detail, the foregoing description is in all aspects illustrative and not restrictive. It is therefore understood that numerous modifications and variations can be devised without departing from the scope of the invention.

What is claimed is:

1. A semiconductor manufacturing apparatus to manufacture a semiconductor device, the semiconductor manufacturing apparatus comprising:
a wire supply to supply a wire;
a tool to bond the wire supplied by the wire supply to a plurality of bonded portions of the semiconductor device;
a first blade to half cut a remaining portion of the wire other than a portion between the plurality of bonded portions; and
a second blade to cut the half cut portion of the wire, the second blade having a cutting edge whose angle is an acute angle smaller than an angle of a cutting edge of the first blade.

2. The semiconductor manufacturing apparatus according to claim 1, further comprising:
a damper mechanism to move the first blade; and
a motor to move the second blade.

3. The semiconductor manufacturing apparatus according to claim 1, wherein
the angle of the cutting edge of the first blade is an obtuse angle.

4. The semiconductor manufacturing apparatus according to claim 2, wherein
the angle of the cutting edge of the first blade is an obtuse angle.

5. A semiconductor device comprising:
a semiconductor element; and
a wire connected to the semiconductor element and having two different continuous cut surfaces.

6. The semiconductor device according to claim 5, wherein
the wire is a wire having a diameter of 100 μm or more and 600 μm or less and formed of metal having a higher hardness than aluminum.

7. The semiconductor device according to claim 5, wherein
the wire is a ribbon wire.

8. The semiconductor device according to claim 6, wherein
the wire is a ribbon wire.
